(19) United States
(12) Patent Application Publication
(10) Pub. No.: US 2026/0290487 A1
(43) Pub. Date: Sep. 24, 2026

(54) SEMICONDUCTOR MEMORY DEVICE

(71) Applicant: Kioxia Corporation, Tokyo (JP)

(72) Inventor: Akio KANEKO, Kamakura Kanagawa (JP)

(73) Assignee: Kioxia Corporation, Tokyo (JP)

(21) Appl. No.: 19/240,651

(22) Filed: Jun. 17, 2025

(30) Foreign Application Priority Data
Mar. 18, 2025 (JP) 2025-044074

(51) Int. Cl. G11C 29/52; G11C 16/08; G11C 16/24; G11C 16/26

(52) U.S. Cl. CPC G11C 29/52; G11C 16/08; G11C 16/24; G11C 16/26

(57) ABSTRACT

A semiconductor memory device includes a memory string including a plurality of memory cells connected in series; a plurality of bit lines connected to one end of each of the memory strings, a source line connected in common to the other ends of the memory strings; a plurality of word lines connected to each of the memory cells; and a controller that executes a read operation by applying a first voltage increasing toward a read voltage to a selected word line, applying a second voltage increasing toward a read pass voltage to unselected word lines to detect change in currents or voltages of the bit lines, and corrects the read voltage based on the changes in currents or voltages during a first period, and reading data from the selected memory cell based on the corrected read voltage during a second period following the first period.

### CROSS-REFERENCE TO RELATED APPLICATIONS

This application is based upon and claims the benefit of Japanese Patent Application No. 2025-044074, filed on Mar. 18, 2025, the entire contents of which are incorporated herein by reference.

### BACKGROUND

### Field

Embodiments described herein relate generally to a semiconductor memory device.

### Description of the Related Art

A semiconductor memory device is known that includes a plurality of memory cells connected in series and a memory string in which each of the plurality of memory cells is capable of storing a plurality of threshold values. This type of semiconductor memory device includes a plurality of bit lines connected to one end of each of the plurality of memory strings, a source line connected in common to the other end of the plurality of memory strings, and a plurality of word lines connected to each of the plurality of memory cells. In a semiconductor memory device of this type, during a read operation, a read voltage is applied to the selected word lines and, at the same time, a read pass voltage larger than the read voltage is applied to the unselected word lines, so that data is read out from the selected memory cells.

### BRIEF DESCRIPTION OF THE DRAWINGS

FIG. 1 is a schematic block diagram illustrating a configuration of a memory die MD according to a first embodiment;

FIG. 2 is a schematic circuit diagram illustrating a part of the configuration of the memory die MD;

FIG. 3 is a schematic circuit diagram illustrating configurations of a voltage generation circuit VG, a driver circuit DRV, and a row decoder RD;

FIG. 4 is a schematic block diagram illustrating configurations of a row control circuit RowC and a block decoder BLKD;

FIG. 5 is a schematic block diagram illustrating a configuration of a sense amplifier module SAM;

FIG. 6 is a schematic circuit diagram illustrating a configuration of a sense amplifier unit SAU;

FIG. 7 is a schematic block diagram illustrating a configuration of a tracking circuit TRC;

FIG. 8 is a schematic diagram illustrating a relationship between a distribution of threshold voltages of memory cells MC, stored data, and read voltages;

FIG. 9 is a schematic diagram illustrating a relationship between changes in the threshold voltages of the memory cells MC and the read voltages;

FIG. 10 is a schematic waveform diagram illustrating a read operation of the memory cell MC according to the first embodiment;

FIG. 11 is a schematic waveform diagram illustrating details of a first period in FIG. 10;

FIGS. 12A, 12B, and 12C are schematic diagrams illustrating the distributions of the threshold voltages of memory cell MC and relationships between the first voltage V1 and the second voltage V2 at each time;

FIG. 13 is a schematic waveform diagram of a read operation of a second embodiment;

FIG. 14 is a schematic block diagram illustrating a configuration of a memory die MD according to a third embodiment;

FIG. 15 is a circuit diagram illustrating an example of a source current detection circuit SIDC;

FIG. 16 is a schematic waveform diagram illustrating a read operation of a memory cell MC according to the third embodiment;

FIG. 17 is a schematic waveform diagram illustrating details of the first period in FIG. 16;

FIG. 18 is a schematic cross-sectional view illustrating a schematic configuration of a memory die MD according to a fourth embodiment; and

FIG. 19 is a schematic cross-sectional view illustrating a schematic configuration of a memory die MD according to a fifth embodiment.

### DETAILED DESCRIPTION

A semiconductor memory device according to one embodiment comprises: a plurality of memory strings each including a plurality of memory cells connected in series, the plurality of memory cells being able to store a respective plurality of threshold values; a plurality of bit lines connected to one end of each of the plurality of memory strings; a source line connected in common to the other ends of the plurality of memory strings; a plurality of word lines connected to each of the plurality of memory cells; and a controller that executes a read operation. The controller applies a first voltage increasing toward a read voltage to a selected word line among the plurality of word lines and applies a second voltage increasing toward a read pass voltage larger than the read voltage to unselected word lines among the plurality of word lines during a first period included in a read operation period, detects changes in currents flowing through the plurality of bit lines or changes in voltages of the plurality of bit lines, and corrects the read voltage based on the changes in the currents or the changes in the voltages during the first period. The controller executes a read operation by reading data from the selected memory cell based on the corrected read voltage during a second period following the first period included in the read operation period.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a predetermined plane may be referred to as a first direction, a direction along this predetermined plane may be referred to as a second direction, and a direction intersecting with the second direction along this predetermined plane may be referred to as a third direction. These first direction, second direction, and third direction may each correspond to any of the Z-direction, the X-direction, and the Y-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion at a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

In this specification, when referring to a “wiring”, this may include a wiring, a via-contact electrode, a connecting portion for connecting a wiring to a via-contact electrode, a bonding electrode, or the like.

### First Embodiment

### Circuit Configuration of Memory Die MD

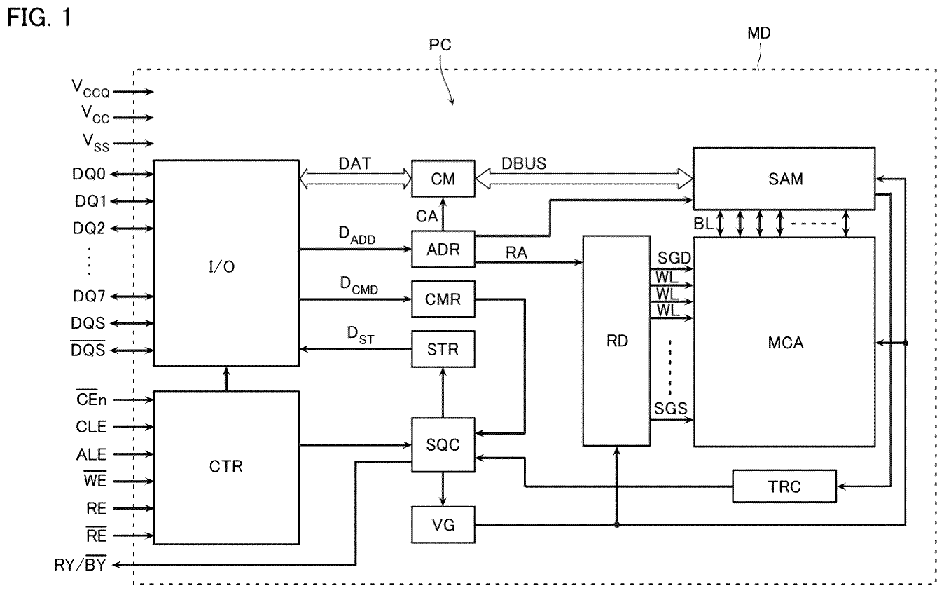

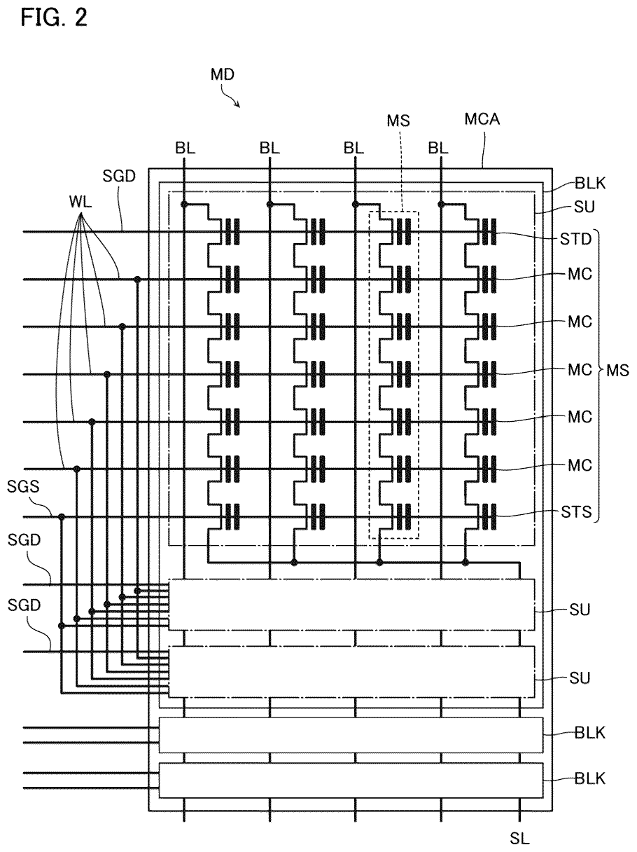

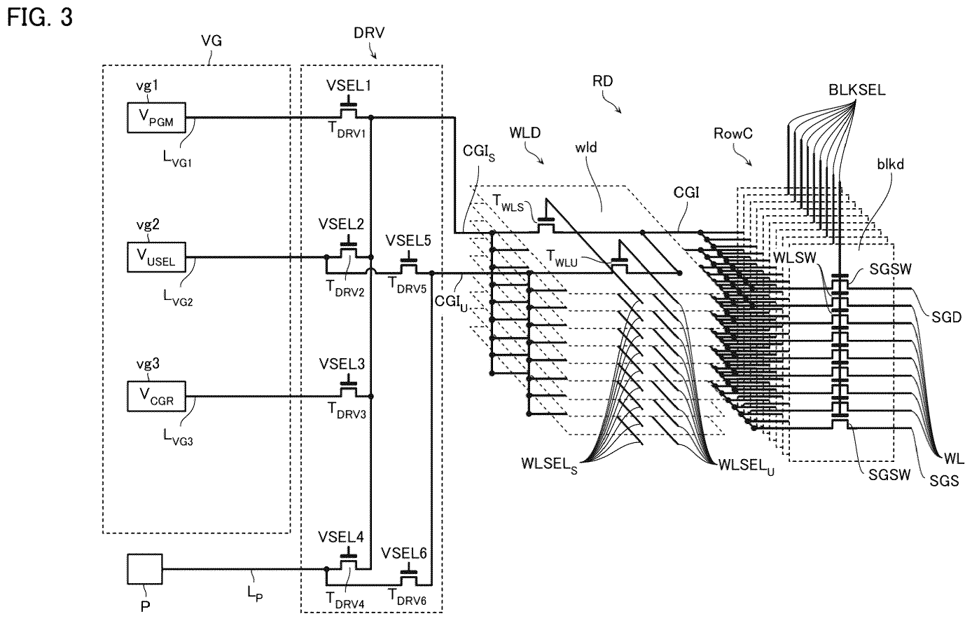

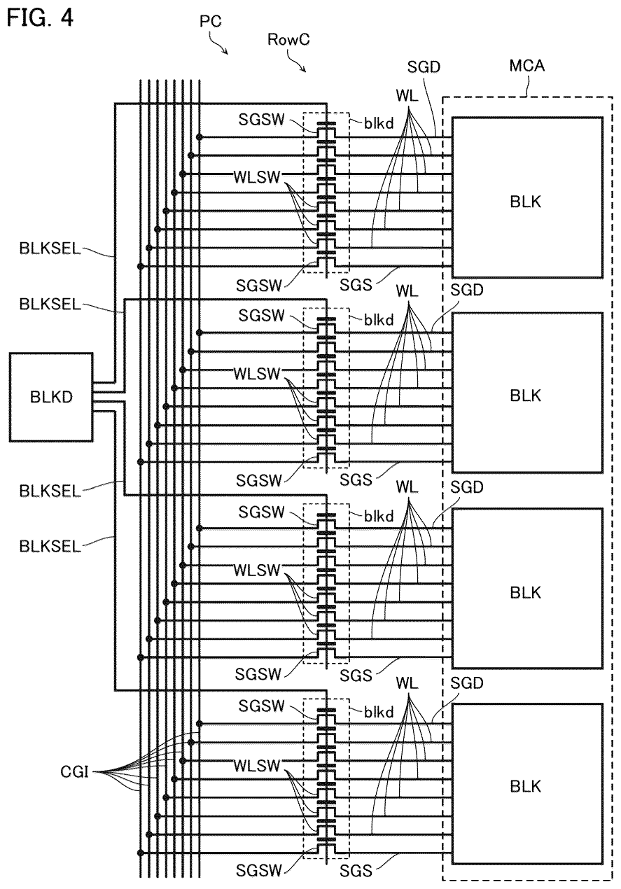

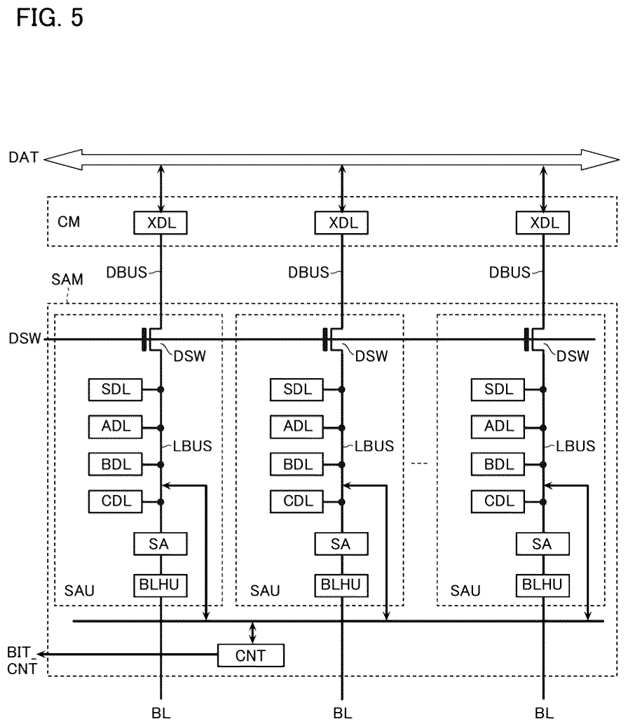

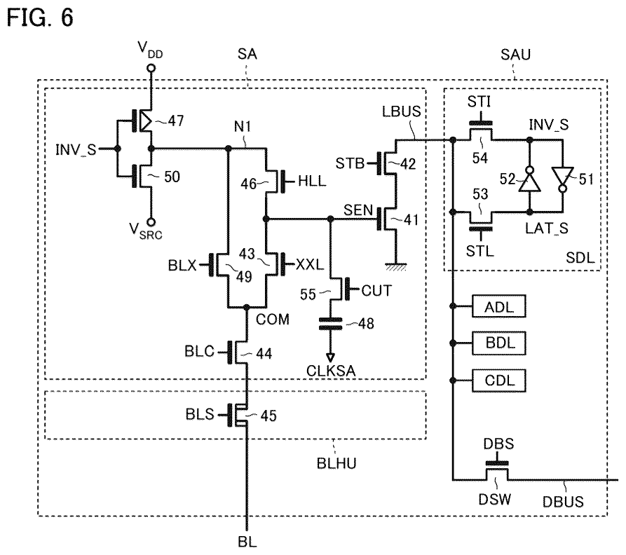

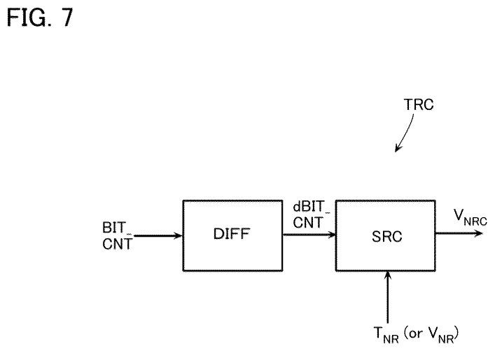

FIG. 1 is a schematic block diagram illustrating a configuration of a memory die MD according to a first embodiment. FIG. 2 is a schematic circuit diagram illustrating a part of the configuration of the memory die MD. FIG. 3 is a schematic circuit diagram illustrating configurations of a voltage generation circuit VG, a driver circuit DRV, and a row decoder RD. FIG. 4 is a schematic block diagram illustrating configurations of a row control circuit RowC and a block decoder BLKD. FIG. 5 is a schematic block diagram illustrating a configuration of a sense amplifier module SAM. FIG. 6 is a schematic circuit diagram illustrating a configuration of a sense amplifier unit SAU. FIG. 7 is a schematic block diagram illustrating a configuration of a tracking circuit TRC.

FIG. 1 illustrates a plurality of control terminals and the like. These plurality of control terminals are expressed as control terminals corresponding to high active signals (positive logic signals) in some cases. The plurality of control terminals are expressed as control terminals corresponding to low active signals (negative logic signals) in some cases. The plurality of control terminals are expressed as control terminals corresponding to both of the high active signals and the low active signals in some cases. In FIG. 1, reference numerals of the control terminals corresponding to the low active signals include overlines (overbars). In this specification, a reference numeral of the control terminal corresponding to the low active signal includes a slash (“/”). Note that the description in FIG. 1 is an example, and the specific aspect is appropriately adjustable. For example, a part of or all of the high active signals can be changed to the low active signals, or a part of or all of the low active signals can be changed to the high active signals.

As illustrated in FIG. 1, a memory die MD includes a memory cell array MCA and a peripheral circuit PC that constitutes a controller. The peripheral circuit PC includes the voltage generation circuit VG, the row decoder RD, a sense amplifier module SAM, a tracking circuit TRC, and a sequencer SQC. The peripheral circuit PC includes a cache memory CM, an address register ADR, a command register CMR, and a status register STR. The peripheral circuit PC includes an input/output control circuit I/O and a logic circuit CTR.

### Circuit Configuration of Memory Cell Array MCA

As illustrated in FIG. 2, the memory cell array MCA includes a plurality of memory blocks BLK. Each of these plurality of memory blocks BLK includes a plurality of string units SU. Each of these plurality of string units SU includes a plurality of memory strings MS. These plurality of memory strings MS have one ends each connected to the peripheral circuit PC via bit lines BL. These plurality of memory strings MS have the other ends each connected to the peripheral circuit PC via a common source line SL.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores data of 1 bit or a plurality of bits. Respective word lines WL are connected to the gate electrodes of the plurality of memory cells MC corresponding to one memory string MS. Each of these word lines WL is connected in common to all of the memory strings MS in one memory block BLK.

The select transistors (STD, STS) are field-effect type transistors. The select transistors (STD, STS) each include a semiconductor layer, a gate insulating film, and a gate electrode. The semiconductor layer functions as a channel region. The gate insulating film may include an electric charge accumulating layer. The select gate lines (SGD, SGS) are connected to the gate electrodes of the select transistors (STD, STS), respectively. One drain-side select gate line SGD is connected to all of the memory strings MS in one string unit SU in common. One source-side select gate line SGS is connected in common to all of the memory strings MS in one memory block BLK. The respective drain-side select gate line SGD and source-side select gate line SGS may be referred to as select gate line SG.

### Circuit Configuration of Voltage Generation Circuit VG

For example, as illustrated in FIG. 3, the voltage generation circuit VG (FIG. 1) includes a plurality of voltage generation units vg1 to vg3. The voltage generation units vg1 to vg3 generate voltages of predetermined magnitudes and output them via voltage supply lines L_{VG} in a read operation, a write operation, and an erase operation. For example, the voltage generation unit vg1 outputs a program voltage in the write operation. The voltage generation unit vg2 outputs a read pass voltage in the read operation. The voltage generation unit vg2 outputs a write pass voltage in the write operation. The voltage generation unit vg3 outputs a read voltage in the read operation. The voltage generation unit vg3 outputs a verify voltage in the write operation. For example, the voltage generation units vg1 to vg3 may be a step-up circuit, such as a charge pump circuit, or may be a step-down circuit, such as a regulator. These step-down circuit and step-up circuit are each connected to a voltage supply line L_{P}. The voltage supply line L_{P} is applied with a power supply voltage V_{CC} or a ground voltage V_{SS} (FIG. 1). These voltage supply lines L_{P} are connected to pad electrodes P, for example. The operating voltage output from the voltage generation circuit VG is appropriately adjusted in accordance with control signals from the sequencer SQC.

The voltage generation circuit VG (FIG. 1) described with reference to FIG. 3 has a configuration that generates the program voltage, the read pass voltage, the write pass voltage, the read voltage, and the verify voltage applied to the word lines WL via a wiring CGI. However, the voltage generation circuit VG can generate not only the operating voltages applied to the word lines WL, but also a plurality of patterns of operating voltages applied to the bit line BL, the source line SL, and the select gate lines (SGD, SGS) at the read operation, the write operation, and the erase operation on the memory cell array MCA and output them to a plurality of voltage supply lines. These operating voltages are appropriately adjusted in accordance with the control signal from the sequencer SQC.

### Circuit Configuration of Row Decoder RD

For example, as illustrated in FIG. 3, the row decoder RD includes a row control circuit RowC, a word line decoder WLD, a driver circuit DRV, and an address decoder (not illustrated). For example, as illustrated in FIG. 4, the row control circuit RowC includes a plurality of block decoder units blkd and the block decoder BLKD.

The plurality of block decoder units blkd correspond to the plurality of memory blocks BLK in the memory cell array MCA. The block decoder unit blkd includes a plurality of word line switches WLSW and a plurality of select gate line switches SGSW. The plurality of word line switches WLSW correspond to the plurality of word lines WL in the memory block BLK. The plurality of select gate line switches SGSW correspond to the drain-side select gate line SGD and the source-side select gate line SGS in the memory block BLK.

The word line switch WLSW and the select gate line switch SGSW are, for example, field-effect type NMOS transistors. The word line switch WLSW has a drain electrode connected to the word line WL. The select gate line switches SGSW have drain electrodes connected to the drain-side select gate line SGD and the source-side select gate line SGS. The word line switch WLSW and the select gate line switch SGSW have source electrodes connected to the wirings CGI. The wiring CGI is connected to all of the block decoder units blkd in the row control circuit RowC. The word line switches WLSW and the select gate line switches SGSW have gate electrodes connected to a signal line BLKSEL. A plurality of the signal lines BLKSEL are disposed corresponding to all of the block decoder units blkd. Additionally, the signal line BLKSEL is connected to all of the word line switches WLSW and the select gate line switches SGSW in the block decoder unit blkd.

The block decoder BLKD decodes the block address at, for example, the read operation and the write operation. In the read operation, the write operation, or the like, for example, one signal line BLKSEL corresponding to the block address in the address register ADR (FIG. 1) enters an “H” state and the other signal lines BLKSEL enter an “L” state. For example, a predetermined driving voltage having a positive magnitude is applied to one signal line BLKSEL, and the ground voltage V_{SS} and the like are applied to the other signal lines BLKSEL. Accordingly, all of the word lines WL and the select gate line SG in one memory block BLK corresponding to this block address are electrically conductive to all of the wirings CGI. Additionally, all of the word lines WL and the select gate lines SG in the other memory blocks BLK enter a floating state.

The word line decoder WLD includes a plurality of word line decode units wld. The plurality of word line decode units wld correspond to the plurality of memory cells MC in the memory string MS. In the example of FIG. 3, the word line decode unit wld includes two transistors T_{WLS}, T_{WLU}. The transistors T_{WLS}, T_{WLU} are, for example, field-effect type NMOS transistors. The transistors T_{WLS}, T_{WLU} have drain electrodes connected to the wiring CGI. The transistor T_{WLS} has a source electrode connected to a wiring CGI_{S}. The transistor T_{WLU} has a source electrode connected to a wiring CGI_{U}. The transistor T_{WLS} has a gate electrode connected to a signal line WLSEL_{S}. The transistor T_{WLU} has a gate electrode connected to a signal line WLSEL_{U}. The plurality of signal lines WLSEL_{S} are disposed corresponding to one transistors T_{WLS} included in all of the word line decode units wld. The plurality of signal lines WLSEL_{U} are disposed corresponding to the other transistors T_{WLU} included in all of the word line decode units wld.

In the read operation, the write operation, and the like, for example, the signal line WLSEL_{S} corresponding to one word line decode unit wld corresponding to a page address in the address register ADR (FIG. 1) enters the “H” state, and the signal line WLSEL_{U} corresponding to the one word line decode unit wld enters the “L” state. Further, the signal lines WLSEL_{S} corresponding to the other word line decode units wld enter the “L” state, and the signal lines WLSEL_{U} corresponding to the other word line decode units wld enter the “H” state. A voltage corresponding to the selected word line WL is applied to the wiring CGI_{S}. Voltages corresponding to the unselected word lines WL are applied to the wirings CGI_{U}. Thus, the voltage corresponding to the selected word line WL is applied to the one word line WL corresponding to the above-described page address. Additionally, the voltages corresponding to the unselected word lines WL are applied to the other word lines WL.

The driver circuit DRV, for example, includes six transistors T_{DRV1} to T_{DRV6}. The transistors T_{DRV1} to T_{DRV6} are, for example, field-effect type NMOS transistors. The transistors T_{DRV1} to T_{DRV4} have drain electrodes connected to the wiring CGI_{S}. The transistors T_{DRV5}, T_{DRV6} have drain electrodes connected to the wiring CGI_{U}. The transistor T_{DRV1} has a source electrode connected to an output terminal of the voltage generation unit vg1 via a voltage supply line L_{VG1}. The transistors T_{DRV2}, T_{DRV5} have source electrodes connected to an output terminal of the voltage generation unit vg2 via the voltage supply line L_{VG2}. The transistor T_{DRV3} has a source electrode connected to an output terminal of the voltage generation unit vg3 via the voltage supply line L_{VG3}. The transistors T_{DRV4}, T_{DRV6} have source electrodes connected to the pad electrode P via the voltage supply line L_{P}. The transistors T_{DRV1} to T_{DRV6} have gate electrodes to which signal lines VSEL1 to VSEL6 are connected, respectively.

In the read operation, the write operation, and the like, for example, one of the plurality of signal lines VSEL1 to VSEL4 corresponding to the wiring CGI_{S} enters the “H” state and the others enter the “L” state. Additionally, one of the two signal lines VSEL5, VSEL6 corresponding to the wiring CGI_{U} enters the “H” state and the other enters the “L” state.

The address decoder (not illustrated), for example, sequentially refers to a row address RA of the address register ADR (FIG. 1) in accordance with the control signal from the sequencer SQC (FIG. 1). The row address RA includes the above-described block address and page address. The address decoder controls the voltages of the signal lines BLKSEL, WLSEL_{S}, WLSEL_{U} to the “H” state or the “L” state.

In the example of FIG. 3, in the row decoder RD, one block decoder unit blkd is disposed for one memory block BLK. However, this configuration is appropriately changeable. For example, one block decoder unit blkd may be disposed for two or more of the memory blocks BLK.

### Circuit Configuration of Sense Amplifier Module SAM

FIG. 5 is a schematic block diagram illustrating configurations of the sense amplifier module SAM and the cache memory CM. The sense amplifier module SAM detects the ON state/OFF state of the selected memory cell MC and acquires data indicative of the state of the memory cell MC. This operation is referred to as a sense operation in some cases. The sense amplifier module SAM includes a plurality of sense amplifier units SAU. The plurality of sense amplifier units SAU correspond to the plurality of bit lines BL. Each of the plurality of sense amplifier units SAU includes a sense amplifier SA and latch circuits SDL, ADL, BDL, CDL. Each of the plurality of sense amplifier units SAU includes a bit line connection circuit BLHU. The bit line connection circuit BLHU is a protection circuit for preventing, for example, a high voltage applied to a channel of the memory string MS in an erase operation from being applied to the sense amplifier SA. The bit line connection circuit BLHU may be configured to be able to apply a predetermined voltage to the unselected bit lines BL.

The sense amplifier SA of the sense amplifier unit SAU, and the latch circuits SDL, ADL, BDL, and CDL are connected in common to the bus LBUS. Thus, the latch circuits XDL, the sense amplifier SA, and the latch circuits SDL, ADL, BDL, and CDL are connected such that they can transmit and receive data to and from each other. The bus LBUS is connected to the bus DBUS via the switch transistor DSW.

The sense amplifier module SAM has a counter CNT. The counter CNT is provided in common for the plurality of sense amplifier units SAU. The counter CNT counts the number of on-cell data, that is, the number of memory strings MS in the on state, read out to the latch circuits SDL, ADL, BDL, and CDL, and outputs this count value BIT_CNT to the tracking circuit TRC.

As illustrated in FIG. 6, the sense amplifier SA includes a sense transistor 41, for example. The sense transistor 41 discharges electric charge on the bus LBUS in accordance with the voltage at the sense node SEN, that is, the current flowing through the bit line BL. A source electrode of the sense transistor 41 is connected to the voltage supply line to which the ground voltage V_{SS} is applied. A drain electrode of the sense transistor 41 is connected to the bus LBUS via a switch transistor 42. A gate electrode of the sense transistor 41 is connected to the bit line BL via a sense node SEN, a discharge transistor 43, a node COM, a clamp transistor 44, and a high breakdown voltage transistor 45. The sense node SEN is connected to an internal control signal line CLKSA via a cutoff transistor 55 and a capacitor 48. The cutoff transistor 55 disconnects the sense node SEN and the capacitor 48 during the first period at a start of the read operation.

The sense amplifier SA includes a voltage transfer circuit. The voltage transfer circuit selectively electrically conducts the node COM and the sense node SEN with a voltage supply line to which a voltage V_{DD} is applied or a voltage supply line to which a voltage V_{SRC} is applied in accordance with data latched by the latch circuit SDL. The voltage transfer circuit includes a node N1, a charge transistor 46, a charge transistor 49, a charge transistor 47, and a discharge transistor 50. The charge transistor 46 is connected between the node N1 and the sense node SEN. The charge transistor 49 is connected between the node N1 and the node COM. The charge transistor 47 is connected between the node N1 and the voltage supply line to which the voltage V_{DD} is applied. The discharge transistor 50 is connected between the node N1 and the voltage supply line to which the voltage V_{SRC} is applied. Note that the gate electrodes of the charge transistor 47 and the discharge transistor 50 are connected to a node INV_S of the latch circuit SDL in common.

Note that the sense transistor 41, the switch transistor 42, the discharge transistor 43, the clamp transistor 44, the charge transistor 46, the charge transistor 49, the discharge transistor 50, and the cutoff transistor 55 are, for example, enhancement type NMOS transistors. The high breakdown voltage transistor 45 is, for example, a depletion type NMOS transistor. The charge transistor 47 is, for example, a PMOS transistor.

A gate electrode of the switch transistor 42 is connected to a signal line STB. A gate electrode of the discharge transistor 43 is connected to a signal line XXL. A gate electrode of the clamp transistor 44 is connected to a signal line BLC. The high breakdown voltage transistor 45 has a gate electrode connected to a signal line BLS. A gate electrode of the charge transistor 46 is connected to a signal line HLL. The charge transistor 49 has a gate electrode connected to a signal line BLX. These signal lines STB, XXL, BLC, BLS, HLL, BLX are connected to the sequencer SQC.

The latch circuit SDL includes nodes LAT_S, INV_S, an inverter 51, an inverter 52, a switch transistor 53, and a switch transistor 54. The inverter 51 includes an output terminal connected to the node LAT_S and an input terminal connected to the node INV_S. The inverter 52 includes an input terminal connected to the node LAT_S and an output terminal connected to the node INV_S. The switch transistor 53 is disposed in a current path between the node LAT_S and the bus LBUS. The switch transistor 54 is disposed in a current path between the node INV_S and the bus LBUS. The switch transistors 53 and 54 are, for example, NMOS transistors. The switch transistor 53 has a gate electrode connected to the sequencer SQC via a signal line STL. The switch transistor 54 has a gate electrode connected to the sequencer SQC via a signal line STI.

The latch circuits ADL, BDL, and CDL are configured approximately the same as the latch circuit SDL. However, as described above, the node INV_S of the latch circuit SDL is electrically conducted with the gate electrodes of the charge transistor 47 and the discharge transistor 50 in the sense amplifier SA. The latch circuits ADL, BDL, and CDL are different from the latch circuit SDL in this respect.

The switch transistor DSW is, for example, an NMOS transistor. The switch transistor DSW is connected between the bus LBUS and the bus DBUS. The switch transistor DSW has a gate electrode connected to the sequencer SQC via a signal line DBS.

As exemplified in FIG. 6, the above-described signal lines STB, HLL, XXL, BLX, BLC, BLS, CUT are each connected between all the sense amplifier units SAU included in the sense amplifier module SAM in common. The voltage supply line to which the voltage V_{DD} is applied and the voltage supply line to which the voltage V_{SRC} is applied, described above, are also each connected between all the sense amplifier units SAU included in the sense amplifier module SAM in common. The signal line STI and the signal line STL of the latch circuit SDL are each connected between all the sense amplifier units SAU included in the sense amplifier module SAM in common. Similarly, signal lines ATI, ATL, BTI, BTL, CTI, CTL corresponding to the signal lines STI and the signal lines STL in the latch circuits ADL, BDL, CDL are each connected between all the sense amplifier units SAU included in the sense amplifier module SAM in common. Meanwhile, a plurality of the above-described signal lines DBS are disposed corresponding to all the respective sense amplifier units SAU included in the sense amplifier module SAM.

The configuration of the sense amplifier unit SAU is not limited thereto, and various changes are possible. For example, the number of latch circuits provided in the sense amplifier unit SAU can be designed based on the number of bits of data that can be stored in one memory cell MC.

### Circuit Configuration of Cache Memory CM

As illustrated in FIG. 5, the cache memory CM includes a plurality of latch circuits XDL provided for respective sense amplifier units SAU. The latch circuit XDL temporarily stores read data and write data. The latch circuit XDL is used for input/output of data between an external controller and the sense amplifier unit SAU. Each latch circuit XDL is connected to the corresponding sense amplifier unit SAU via the bus DBUS. It is also possible that one latch circuit XDL is connected to a plurality of sense amplifier units SAU. The plurality of latch circuits are connected to the latch circuits in the sense amplifier modules SAM via a wiring DBUS. Data DAT included in these plurality of latch circuits are sequentially transferred to the sense amplifier module SAM or the input/output control circuit I/O.

A decode circuit and a switch circuit (not illustrated) are connected to the cache memory CM. The decode circuit decodes a column address CA latched in the address register ADR. The switch circuit causes the latch circuit corresponding to the column address CA to electrically conduct with a bus DBUS according to an output signal from a decode circuit.

### Circuit Configuration of Tracking Circuit TRC

The tracking circuit TRC includes, for example, as illustrated in FIG. 7, a differential circuit DIFF and a search circuit SRC. The differential circuit DIFF includes a shift register that inputs a bit count value BIT_CNT output from the sense amplifier module SAM and outputs a difference value dBIT_CNT between the preceding and following data. The search circuit SRC searches for the difference value dBIT_CNT output from the differential circuit DIFF, and based on the rise timing of the difference value dBIT_CNT closest to the expected time value T_{NR} or the expected voltage value V_{NR}, outputs information on the correction amount of the read voltage or the corrected read voltage (hereinafter referred to as the “corrected read voltage”) V_{NRC} to the sequencer SQC.

### Circuit Configuration of Sequencer SQC

The sequencer SQC (FIG. 1) outputs internal control signals to the row decoder RD, the sense amplifier module SAM, and the voltage generation circuit VG in accordance with the command data D_{CMD} latched in the command register CMR and the information on the corrected read voltage V_{NRC} transferred from the tracking circuit TRC. The sequencer SQC outputs status data D_{ST} indicating its own state to the status register STR as appropriate.

The sequencer SQC generates a ready/busy signal and outputs it to the terminal RY//BY. In a period when the terminal RY//BY is in an “L” state (a busy period), access to the memory die MD is basically inhibited. In a period when the terminal RY//BY is in an “H” state (a ready period), access to the memory die MD is permitted.

### Circuit Configuration of Input/Output Control Circuit I/O

The input/output control circuit I/O includes data signal input/output terminals DQ0 to DQ7, toggle signal input/output terminals DQS and /DQS, a plurality of input circuits, a plurality of output circuits, a shift register, and a buffer circuit. The plurality of input circuits, the plurality of output circuits, the shift register, and the buffer circuit are each connected to a terminal to which a power supply voltage V_{CCQ} or the ground voltage V_{SS} is applied.

The data input via the data signal input/output terminals DQ0 to DQ7 is input to the cache memory CM, the address register ADR, or the command register CMR from the buffer circuit in response to the internal control signal from the logic circuit CTR. The data output via the data signal input/output terminals DQ0 to DQ7 is input to the buffer circuit from the cache memory CM or the status register STR in response to the internal control signal from the logic circuit CTR.

The plurality of input circuits include, for example, comparators connected to any of the data signal input/output terminals DQ0 to DQ7 or both of the toggle signal input/output terminals DQS and /DQS. The plurality of output circuits include, for example, Off Chip Drivers (OCD) connected to any of the data signal input/output terminals DQ0 to DQ7 or either of the toggle signal input/output terminals DQS and /DQS.

### Circuit Configuration of Logic Circuit CTR

The logic circuit CTR (FIG. 1) receives external control signals from the external controller die (not illustrated) via external control terminals /CEn, CLE, ALE, /WE, RE, and /RE and outputs the internal control signals to the input/output control circuit I/O according to the external control signal.

### Threshold Voltage of Memory Cell MC

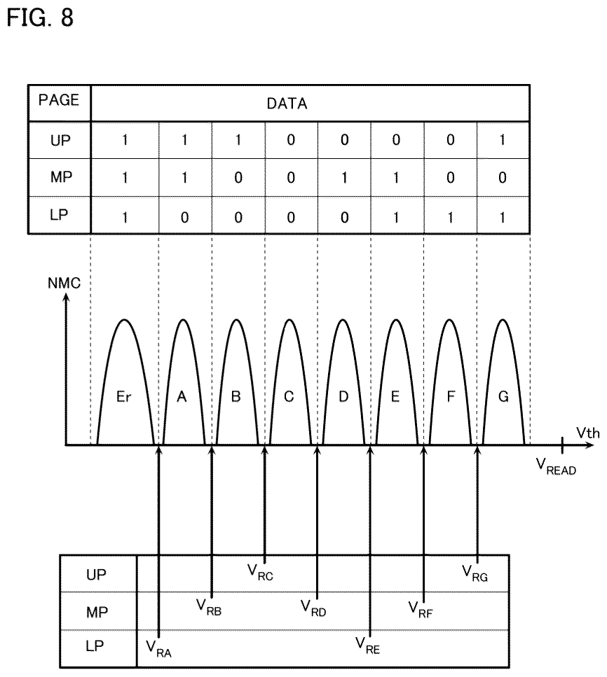

Next, with reference to FIG. 8, the threshold voltage of the memory cell MC is described. FIG. 8 is a schematic diagram illustrating a relationship between a distribution of threshold voltages of the memory cells MC, the stored data, and the read voltages. The horizontal axis of the histogram illustrating the threshold distribution of the memory cells MC indicates the threshold voltages Vth of the memory cells MC, and the vertical axis indicates the number NMC of the memory cells MC.

As described above, the memory cell array MCA includes the plurality of memory cells MC. When the write operation is performed on these plurality of memory cells MC, the threshold voltages of the memory cells MC are controlled to the plurality of patterns of states. FIG. 8 illustrates an example of the distribution of threshold voltages of the memory cells MC controlled in eight states. For example, the threshold voltage of the memory cell MC controlled to a state A is larger than a read voltage V_{RA} in FIG. 8 and smaller than a read voltage V_{RB}. In addition, the threshold voltages of all the memory cells MC are smaller than a read pass voltage V_{READ} in FIG. 8.

In this embodiment, by adjusting the memory cells MC to the eight states, three bits of data are stored in each memory cell MC.

For example, the Er state corresponds to the lowest threshold voltage (the threshold voltage of the memory cell MC in the erased state). The memory cell MC corresponding to the Er state is assigned, for example, the data “111.”

The state A corresponds to the threshold voltage higher than the threshold voltage corresponding to the above-described state Er. For example, data “110” is assigned to the memory cell MC corresponding to the state A.

The state B corresponds to the threshold voltage higher than the threshold voltage corresponding to the state A. For example, data “100” is assigned to the memory cell MC corresponding to the state B.

Similarly, the threshold voltage from the C state to the G state in the figure is higher than the threshold voltage of the B state, and the threshold voltage increases in order from the threshold voltage of the C state to the threshold voltage of the G state. The threshold voltage may be a negative voltage from the Er state to the C state. For example, data “000,” “010,” “011,” “001,” and “101” are assigned to the memory cells MC corresponding to the distribution from the C state to the G state.

In the assignment illustrated in FIG. 8, the data of the low-order bits (low-page: LP) can be distinguished by two read voltages V_{RA} and V_{RE}, the data of the middle-order bits (middle page: MP) can be distinguished by three read voltages V_{RB}, V_{RD}, and V_{RF}, and the data of the high-order bits (high-page: HP) can be distinguished by two read voltages V_{RC} and V_{RG}. This assignment of data is referred to as a 2-3-2 code in some cases. The method of performing read operations for each of the lower page, the middle page, and the upper page is referred to as page read.

The number of bits of the data stored in the memory cell MC, the number of states, the assignment of the data to each state, and the like are changeable as appropriate.

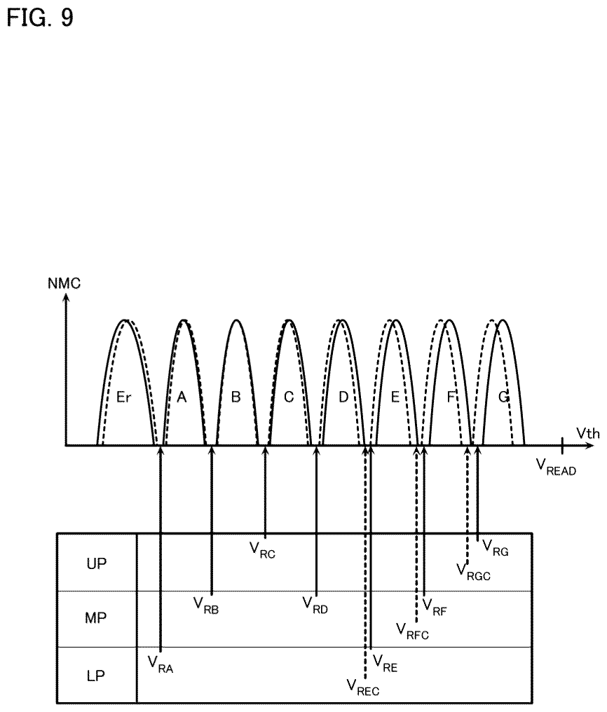

FIG. 9 is a schematic diagram illustrating the relationship between the threshold voltage of the memory cell MC and the read voltage. As illustrated in FIG. 9, after data is written to the memory cells MC, the charge accumulated in each memory cell MC is released over time, and the threshold voltage Vth of each memory cell MC may change. For example, the solid line distribution illustrated in FIG. 9 indicates the threshold voltage distribution immediately after data is written. The dotted lines indicate the threshold voltage distribution after a predetermined time has elapsed since the data has been written to each memory cell MC. In this example, the threshold distributions of the Er state and the A state change in the positive direction, and the threshold voltage distributions of the C state, the D state, the E state, the F state, and the G state change in the negative direction.

When the threshold voltage distribution of the memory cell MC to be read out is as illustrated by the dotted line threshold voltage distribution, the data read out by applying the read voltages V_{RE}, V_{RF}, and V_{RG} to the memory cell MC may be erroneous. For this reason, in this embodiment, the read voltages V_{RE}, V_{RF}, and V_{RG} are corrected during the read operation, and the read operation is performed using the corrected read voltages V_{REC}, V_{RFC}, and V_{RGC}.

### Read Operation

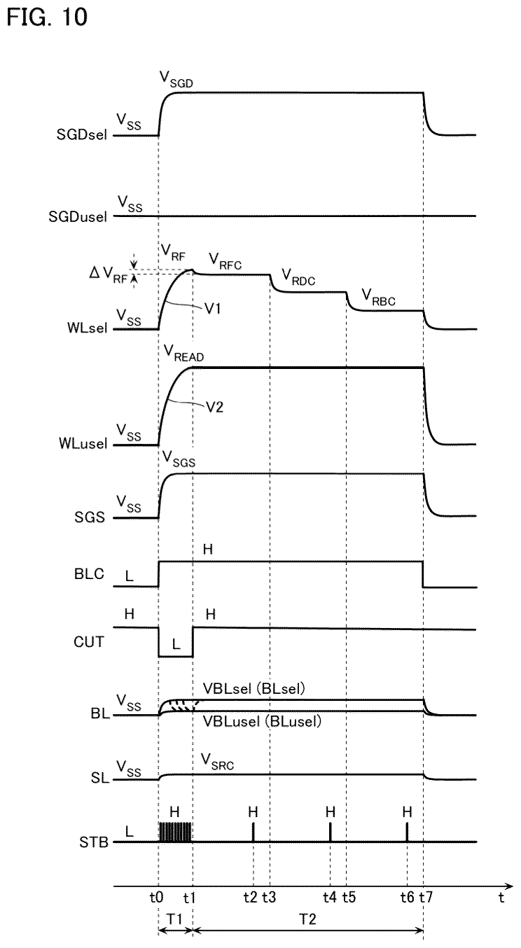

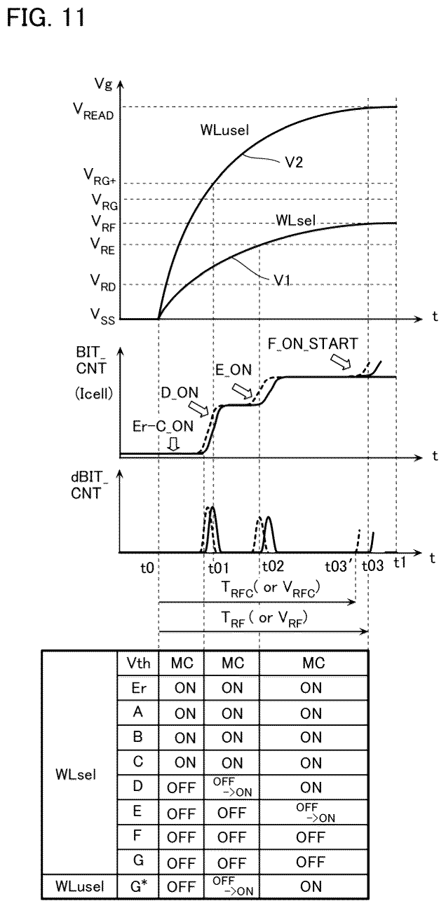

FIG. 10 is a schematic waveform diagram illustrating a read operation of the memory cell MC according to the first embodiment. FIG. 11 is a schematic waveform diagram illustrating details of the first period in FIG. 10. In FIGS. 10 and 11, the data in the middle page MP is read out by three read voltages V_{RB}, V_{RD}, and V_{RF}. The same read operation is possible for the upper page UP and the lower page LP.

The read operation includes a first period T1 for searching for an optimal read voltage value and a second period T2 for executing the read operation using the corrected read voltage adjusted in the first period T1. In the first period T1, an optimal corrected read voltage V_{RFC} between the E state and the F state illustrated in FIG. 9 is generated.

### Read Operation in First Period T1

At time t0, the sequencer SQC applies voltage V_{SGD} to the select gate line SGDsel via the voltage generation circuit VG, and applies the ground voltage V_{SS} to the unselected gate line SGDusel. The sequencer SQC also applies a first voltage V1 increasing toward the read voltage V_{RF} as the expected voltage value to the selected word line WLsel via the voltage generation circuit VG, and applies a second voltage V2 increasing toward the read pass voltage V_{READ} to the unselected word line WLusel. The sequencer SQC also applies a voltage V_{SGS} to the select gate line SGS via the voltage generation circuit VG. The sequencer SQC sets the signal line BLC of the sense amplifier SA to “H” and the signal line CUT to “L,” for turning on the clamp transistor 44 and turning off the cutoff transistor 55.

As a result, the sense amplifier SA connected to the selected bit line BLsel charges the selected bit line BLsel, and the voltage of the selected bit line BLsel rises to the voltage VBLsel. On the other hand, the sense amplifier SA connected to the unselected bit line BLusel charges the unselected bit line BLusel, and the voltage of the unselected bit line BLusel rises to the voltage VBLusel. At time t0, the unselected bit line BLusel need not be charged, and the voltage of the unselected bit line BLusel may be controlled to be maintained at the ground voltage V_{SS}.

In addition, since the cutoff transistor 55 is turned off, the sense node SEN of the sense amplifier SA reflects the voltage VBLsel of the selected bit line BLsel. The voltage of the sense node SEN is sensed at the input timing of the strobe signal continuously input to the signal line STB at a predetermined cycle from time t0 to time t1.

In addition, at time t0, the source line SL is charged to raise the voltage of the source line SL to the voltage V_{SRC}. It is also possible to control the source line SL such that it is not charged at time t0 and the voltage of the source line SL is maintained at the ground voltage V_{SS}.

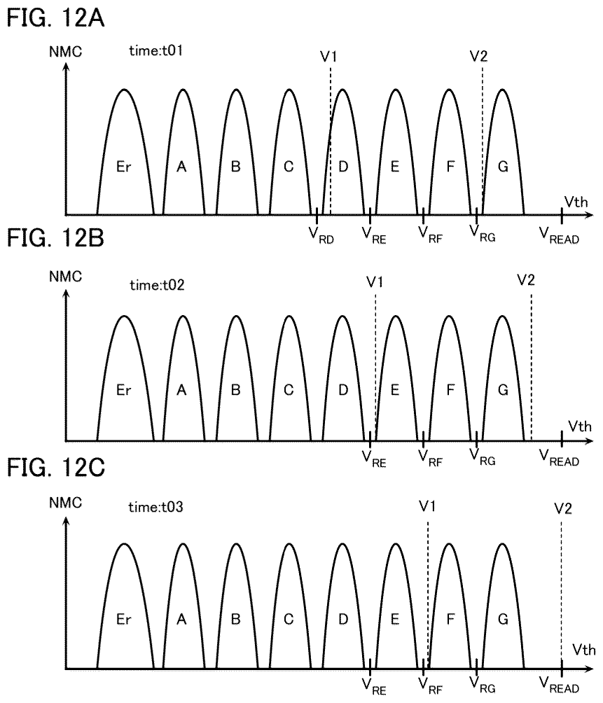

Next, based on FIG. 11, the operation during the first period T1 is described in more detail. Between time t0 and time t01, among the selected memory cells MC connected to the selected word line WLsel, the memory cells MC whose threshold voltage Vth is a negative voltage and whose state is between the Er state and the C state are turned on, and the memory cells MC whose state is between the D state and the G state are turned off. Assuming that any of the memory cells MC included in the memory string MS includes the memory cell MC in the G state, whether or not a cell current Icell flows through each memory string MS is determined by the memory cell MC in the G state. Therefore, as illustrated in FIG. 11, the cell current Icell begins to flow to the memory string MS including the selected memory cell MC from a time immediately before time t01 when the second voltage V2 applied to the unselected word line WLuse exceeds the specified read voltage V_{RG} for reading out the memory cell MC in the G state. Also, when the first voltage V1 applied to the selected word line WLsel at time t01 reaches the specified read voltage V_{RD} for reading out the memory cell MC in the D state, the selected memory cell MC in the D state also turns on. The relationship between each threshold voltage distribution and the first voltage V1 and the second voltage V2 at this time t01 is illustrated in FIG. 12A.

When the selected memory cell MC is a memory cell MC having a threshold voltage Vth between the Er state and the D state, a cell current Icell flows through the memory string MS including the memory cell MC. This causes the voltage of the bit line BL to drop from VBLsel, and the voltage of the sense node SEN of the sense amplifier SA also drops. The sense amplifier SA senses the voltage of the sense node SEN by a strobe signal continuously applied to the signal line STB. The sense results are latched in one of the latch circuits SDL, ADL, BDL, or CDL. When the data latched in the latch circuits SDL, ADL, BDL, or CDL changes, the bit counter CNT (FIG. 5) is counted up. As illustrated in FIG. 11, the count value BIT_CNT of the bit counter CNT increases rapidly before and after time t01, and then becomes constant. The period during which the count value BIT_CNT remains constant corresponds to the threshold voltage Vth period between the D state and the E state.

When the first voltage V1 applied to the selected word line WLsel at time t02 reaches the specified read voltage V_{RE} for reading out the memory cell MC in the E state, the memory cell MC in the E state turns on. At this time t02, the relationship between each threshold voltage distribution and the first voltage V1 and the second voltage V2 is illustrated in FIG. 12B. The second voltage V2 applied to the unselected word line WLusel is larger than the threshold distribution of the G state and smaller than the read pass voltage V_{READ}.

As illustrated in FIG. 11, the count value BIT_CNT of the bit counter CNT increases rapidly when time t02 is exceeded, and then becomes constant. The period during which the bit count value BIT_CNT becomes constant corresponds to the threshold voltage Vth period between the E state and the F state.

When the first voltage V1 applied to the selected word line WLsel at time t03 reaches the specified read voltage V_{RF} for reading out the memory cells MC in the F state, some of the memory cells MC in the F state start to turn on. For this reason, as illustrated in FIG. 11, the count value BIT_CNT of the bit counter CNT increases slightly when time t03 is exceeded. At this time t03, the relationship between each threshold voltage distribution and the first voltage V1 and the second voltage V2 is illustrated in FIG. 12C.

As illustrated in FIG. 11, the bit count value BIT_CNT changes in a staircase pattern, repeating rapid increases and flat sections. This bit count value BIT_CNT is input to the differential circuit DIFF in the tracking circuit TRC (FIG. 7). The differential circuit DIFF outputs the difference dBIT_CNT between the preceding and following bit count values BIT_CNT. As illustrated in FIG. 11, the difference dBIT_CNT becomes a signal that rises at the point where the bit count value BIT_CNT changes.

As illustrated in FIG. 11, the bit count value BIT_CNT and the difference value dBIT_CNT are the specified values illustrated by the solid lines when there is no fluctuation in the threshold voltage Vth. In contrast, when there is a fluctuation in the threshold voltage Vth, the values deviate from the specified values over time, as illustrated by the broken lines. In the example illustrated in the figure, the larger the threshold voltage Vth, the more the threshold voltage Vth is shifted in the direction of becoming smaller than the specified value. Therefore, the search circuit SRC of the tracking circuit TRC (FIG. 7) searches for the difference value dBIT_CNT and searches for the rise timing of the difference value dBIT_CNT closest to the expected time value T_{RF} or the read voltage V_{RF} as the expected voltage value. Based on this search result, the corrected read voltage V_{RFC} information is output to the sequencer SQC.

### Read Operation in Second Period T2

Next, as illustrated in FIG. 10, a read operation for the second period T2 is started following the first period T1. In the second period T2, a data read operation from the selected memory cell MC is performed using the corrected read voltage V_{RFC} adjusted in the first period T1. At this time, the other corrected read voltages V_{RDC} and V_{RBC} used in the same read operation are adjusted based on the corrected read voltage V_{RFC}. That is, from the Er state to the G state, in particular, a certain trend can be observed in the variation of the threshold voltage Vth from the D state to the G state. For this reason, when the corrected read voltages V_{REC}, V_{RFC}, and V_{RGC} on the higher side of the threshold voltage Vth, for example, from the E state to the G state, are determined, the other corrected read voltages V_{RAC} to V_{RDC} can be estimated with high accuracy.

As illustrated in FIG. 10, at time t1, the sequencer SQC maintains the voltage V_{SGD} applied to the select gate line SGDsel and the ground voltage V_{SS} applied to the unselected gate line SGDusel as they are. In addition, the sequencer SQC applies the corrected read voltage V_{RFC} to the selected word line WLsel via the voltage generation circuit VG, and maintains the voltage applied to the unselected word line WLusel at the read pass voltage V_{READ}. The corrected read voltage V_{RFC} is smaller than the specified read voltage V_{RF} by, for example, the voltage ΔV_{RF}. The sequencer SQC also maintains the voltage applied to the select gate line SGS at the voltage V_{SGS}. The sequencer SQC maintains the signal line BLC of the sense amplifier SA at “H” and raises the signal line CUT from “L” to “H.” This turns on the cutoff transistor 55, charges the capacitor 48, and starts normal sense operation.

At time t2, the strobe signal applied to the signal line STB becomes “H.” At this timing, the voltage of the sense node SEN is latched by the latch circuit ADL. When it is determined that the threshold voltage Vth of the selected memory cell MC is equal to or larger than the F state, subsequent latching to the latch circuit ADL is inhibited.

At time t3, sequencer SQC applies the corrected read voltage V_{RDC} to the selected word line WLsel via the voltage generation circuit VG. At time t4, the strobe signal applied to the signal line STB becomes “H.” At this timing, the voltage at the sense node SEN is latched by the latch circuit BDL. When it is determined that the threshold voltage Vth of the selected memory cell MC is in the D state or the E state, subsequent latching to the latch circuit BDL is inhibited.

At time t5, sequencer SQC applies the corrected read voltage V_{RBC} to the selected word line WLsel via the voltage generation circuit VG. At time t6, the strobe signal applied to the signal line STB becomes “H.” At this timing, the voltage at the sense node SEN is latched by the latch circuit CDL.

With the above operations, the operation of reading out the data of the middle page MP by the three corrected read voltages V_{RBC}, V_{RDC}, and V_{RFC} is completed. The same read voltage correction operation and the read operation are possible for the upper page UP and the lower page LP.

### Effect of First Embodiment

According to the first embodiment, the threshold voltage Vth of the memory cell MC is measured during the first period T1 of the read operation, which corresponds to the waiting time before the sense operation of the normal read operation, and the read voltage is adjusted such that it can be reflected in the read operation in the subsequent second period T2. Thus, the read operation can be performed accurately and efficiently. In addition, since the capacitor 48 is disconnected from the sense node SEN during the first period T1, the sense operation of the voltage of the bit line BL can be performed accurately and at high speed.

### Second Embodiment

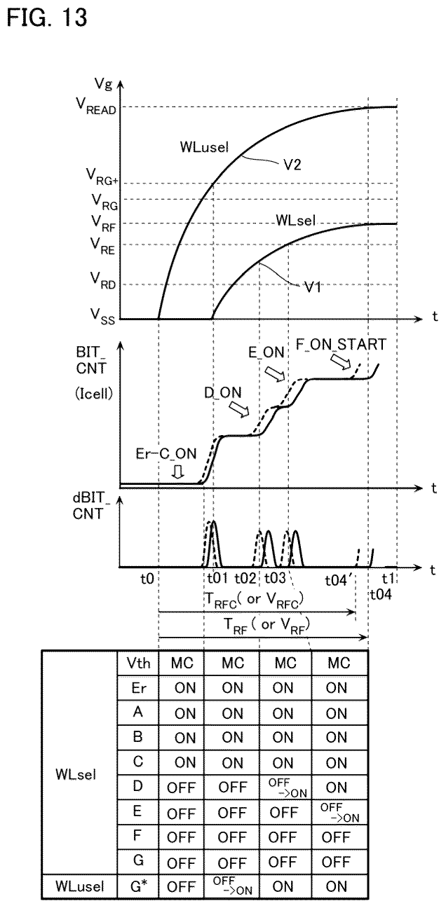

FIG. 13 is a schematic waveform diagram of the read operation in the second embodiment. The circuit configuration of the second embodiment is the same as that of the first embodiment. The read operation of the second embodiment is basically the same as the read operation illustrated in FIG. 10. The read operation of the second embodiment differs from the read operation of the first embodiment in the search operation for the read voltage during the first period T1.

In the second embodiment, the read operation also has the first period T1 for searching for the optimal read voltage value and the second period T2 for executing the read operation using the corrected read voltage adjusted in the first period T1. In the first period T1, the optimal corrected read voltage V_{RFC} between the E state and the F state illustrated in FIG. 9 is generated.

In the second embodiment, the timing of starting to apply the first voltage V1 to the selected word line WLsel is delayed with respect to the timing of starting to apply the second voltage V2 to the unselected word line WLusel. That is, from time t0, a second voltage V2 increasing toward the read pass voltage V_{READ} is applied to the unselected word line WLusel, and from time t01, which is later than time t0, a first voltage V1 increasing toward the read voltage V_{RF} as the expected voltage value is applied to the selected word line WLsel.

Between time t0 and time t01, among the selected memory cells MC connected to the selected word line WLsel, the memory cells MC whose threshold voltage Vth is negative voltage and whose state is between the Er state and the C state are turned on, and the memory cells MC whose threshold voltage Vth is between the D state and the G state are turned off. At time t01, the second voltage V2 applied to the unselected word line WLusel exceeds the specified read voltage V_{RG} for reading out the memory cells MC in the G state. From the time immediately before time t01, the cell current Icell begins to flow through the memory string MS including the selected memory cell MC in between the Er state and the C state. Then, until time t02, the first voltage V1 applied to the selected word line WLsel becomes the voltage between the C state and the D state, and thus the cell current Icell remains constant. At time t02, when the first voltage V1 applied to the selected word line WLsel reaches the specified read voltage V_{RD} for reading out the memory cell MC in the D state, the memory cell MC in the D state also turns on.

When the selected memory cell MC is a memory cell MC having a threshold voltage Vth for the D state, a cell current Icell flows through the memory string MS including the memory cell MC. Thereafter, the period during which the cell current Icell becomes constant corresponds to the threshold voltage period Vth between the D state and the E state.

When the first voltage V1 applied to the selected word line WLsel at time t03 reaches the specified read voltage V_{RE} for reading out the memory cell MC in the E state, the memory cell MC in the E state turns on. The second voltage V2 applied to the unselected word line WLusel is larger than the threshold distribution of the G state and smaller than the read pass voltage V_{READ}.

As illustrated in FIG. 13, the count value BIT_CNT of the bit counter CNT increases rapidly when time t03 is exceeded, and then becomes constant. The period during which the bit count value BIT_CNT becomes constant corresponds to the threshold voltage Vth period between the E state and the F state.

When the first voltage V1 applied to the selected word line WLsel at time t04 reaches the specified read voltage V_{RF} for reading out the memory cells MC in the F state, some of the memory cells MC in the F state start to turn on. As a result, as illustrated in FIG. 13, the count value BIT_CNT of the bit counter CNT slightly increases when it exceeds time t04.

As illustrated in FIG. 13, the bit count value BIT_CNT changes in a staircase pattern, repeating rapid increases and flat sections. In this embodiment, a position of the lower skirt of the D state threshold voltage Vth is clearer than in the first embodiment. The difference value dBIT_CNT becomes a signal that rises at the part where the bit count value BIT_CNT changes.

As illustrated in FIG. 13, changes in the bit count value BIT_CNT and the difference value dBIT_CNT are the specified values illustrated by the solid lines when there is no fluctuation in the threshold voltage Vth. In contrast, when there is a fluctuation in the threshold voltage Vth, the values deviate from the specified values over time, as illustrated by the broken lines. In the example illustrated in the figure, the larger the threshold voltage Vth, the smaller the threshold voltage Vth becomes with respect to the specified value. Therefore, the search circuit SRC of the tracking circuit TRC (FIG. 7) searches for the difference value dBIT_CNT and searches for the rise timing of the difference value dBIT_CNT closest to the expected time value T_{RF} or the read voltage V_{RF} as the expected voltage value. Based on this search result, the corrected read voltage V_{RFC} information is output to the sequencer SQC.

### Effect of Second Embodiment

According to the second embodiment, in addition to the effects of the first embodiment, since the position of the lower skirt of the threshold voltage Vth of the D state is made clear, the corrected read voltage V_{RDC} of the D state can also be estimated with high accuracy.

### Third Embodiment

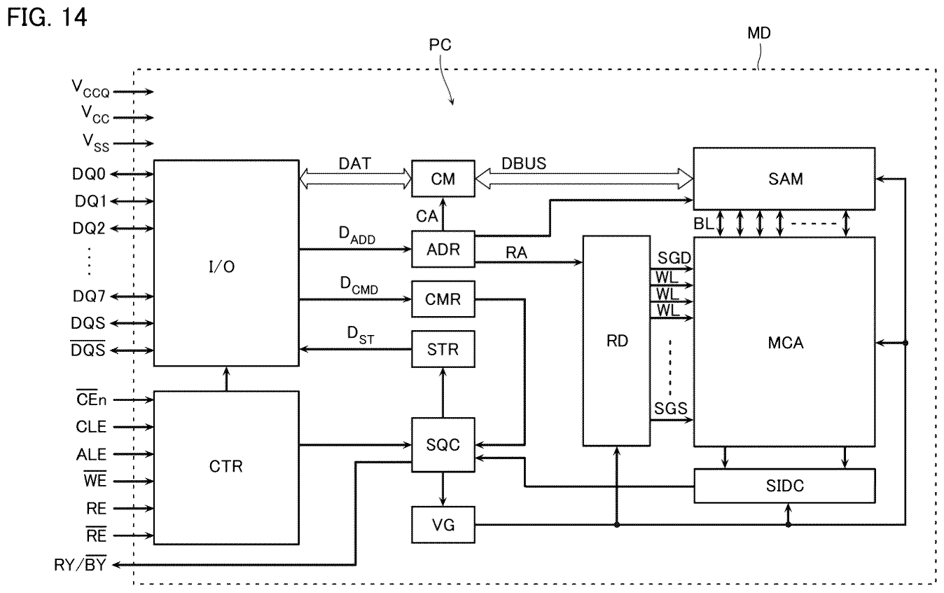

FIG. 14 is a schematic block diagram illustrating a configuration of a memory die MD according to the third embodiment. The memory die MD according to the third embodiment includes a source current detection circuit SIDC instead of the tracking circuit TRC included in the memory die MD of the first embodiment illustrated in FIG. 1. Other configurations of the memory die MD in FIG. 14 are the same as those of the memory die MD in FIG. 1. Therefore, a description of the overlapping configurations is omitted.

As illustrated in FIG. 14, a source current detection circuit SIDC is connected to the source wiring of the memory cell array MCA. When the source lines SL of the memory cell array MCA are electrically separated for each memory block BLK or for each memory plane, the source current detection circuit SIDC is provided for each memory block BLK or for each memory plane.

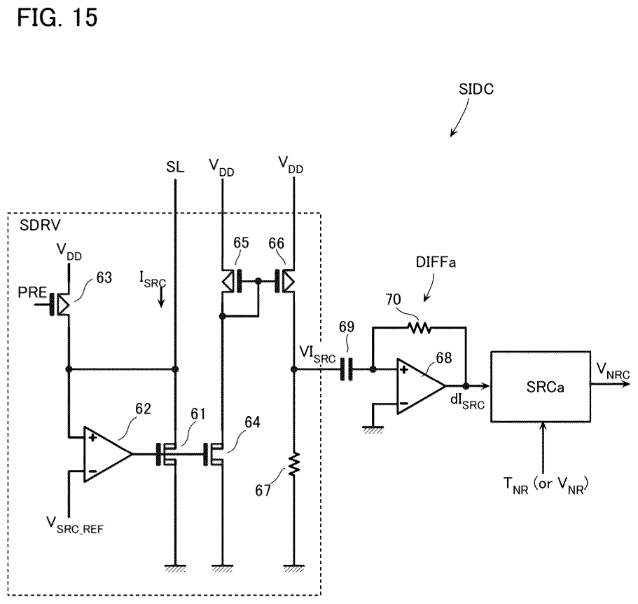

FIG. 15 is a circuit diagram illustrating an example of a source current detection circuit SIDC. The source current detection circuit SIDC includes a source driver circuit SDRV, a differential circuit DIFFa, and a search circuit SRCa.

The source driver circuit SDRV detects the source current I_{SRC} flowing in the source line SL and outputs an output voltage VI_{SRC} proportional to the source current I_{SRC}. The source driver circuit SDRV includes drive transistors 61, 64, an operational amplifier 62, a transistor 63 for precharge, transistors 65, 66, and a resistor 67. The drive transistor 61 is an N-channel MOS transistor and is connected between the source line SL and the grounding terminal. The first input terminal of the operational amplifier 62 is connected to the source line SL. A reference voltage V_{SRC_REF} is applied to the second input terminal of the operational amplifier 62. The output terminal of the operational amplifier 62 is connected to the gate terminal of the drive transistor 61. The transistor 63 is a P-channel MOS transistor and is connected between the power supply terminal to which the power supply voltage V_{DD} is applied and the source line SL. The gate terminal of transistor 63 is connected to the signal line PRE to which the precharge signal is input. The transistor 65 and the drive transistor 64 are connected in series between the power supply terminal to which the voltage V_{DD} is applied and the grounding terminal. The transistor 65 is a P-channel transistor, and its gate terminal is connected to the drain terminal. The drive transistor 64 is an N-channel MOS transistor formed in the same manner as the drive transistor 61, and together with the drive transistor 61 constitutes a current mirror circuit. The transistor 66 and the resistor 67 are connected in series between the power supply terminal to which the power supply voltage V_{DD} is applied and the grounding terminal. The transistor 66 is a P-channel transistor, shares the gate terminal with the transistor 65, and together with the transistor 65 constitutes a current mirror circuit. From the connection node of the transistor 66 and the resistor 67, an output voltage VI_{SRC} proportional to the source current I_{SRC} flowing in the source line SL is output.

The differentiation circuit DIFFa differentiates the output voltage VI_{SRC} output from the source driver circuit SDRV and outputs the differentiation signal dI_{SRC}. The differentiation circuit DIFFa includes an operational amplifier 68, a capacitor 69, and a resistor 70. The output voltage VI_{SRC} from the source driver circuit SDRV is input to the first input terminal of the operational amplifier 68 through the capacitor 69. The second input terminal of the operational amplifier 68 is connected to the grounding terminal. The output terminal of the operational amplifier 68 outputs the differentiation signal dI_{SRC} and is connected to the first input terminal via the resistor 70.

The search circuit SRCa searches the differentiation signal dI_{SRC} output from the differentiation circuit DIFFa and outputs the information on the corrected read voltage V_{NRC} to the sequencer SQC based on the rise timing of the differentiation signal dI_{SRC} closest to the expected time value T_{NR} or the expected voltage value V_{NR}.

### Read Operation

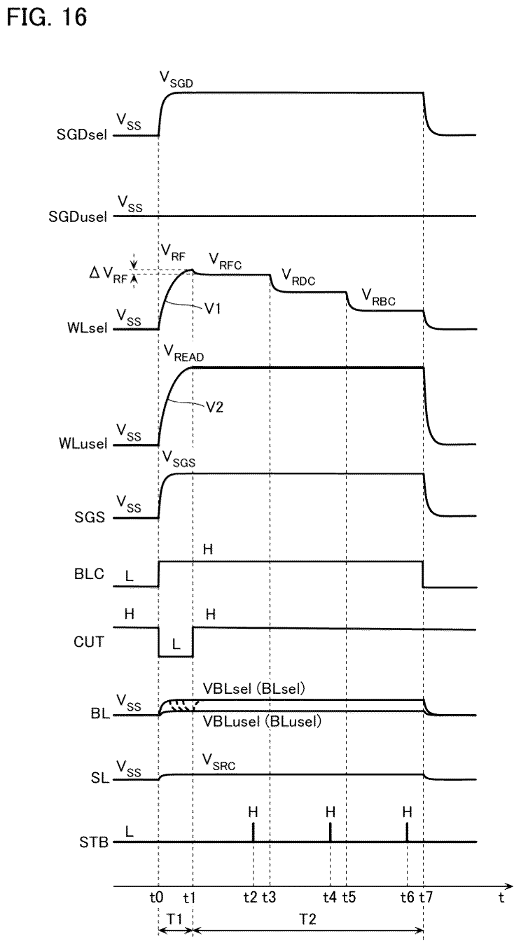

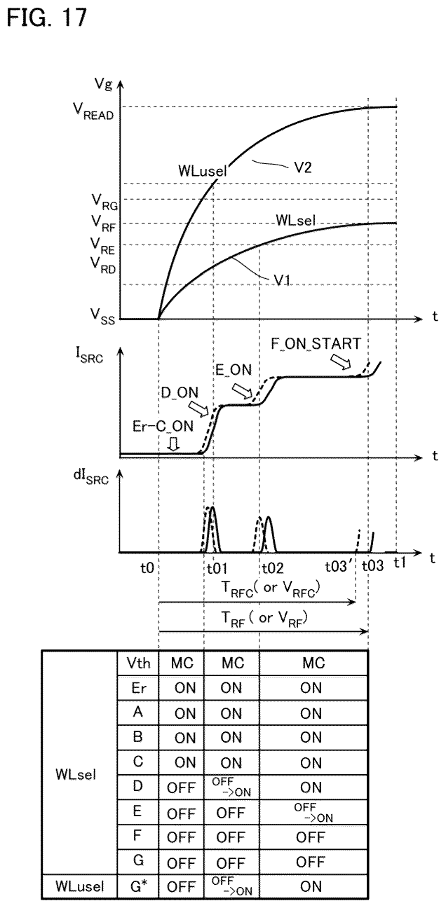

FIG. 16 is a schematic waveform diagram illustrating a read operation of the memory cell MC according to the second embodiment. FIG. 17 is a schematic waveform diagram illustrating details of the first period of FIG. 16. Note that FIGS. 16 and 17 illustrate the read operation of data from the middle page MP by the three read voltages V_{RB}, V_{RD}, and V_{RF}. The same read operation can also be performed for the upper page UP and the lower page LP.

The read operation has the first period T1 for searching for the optimal read voltage value and the second period T2 for executing the read operation using the corrected read voltage adjusted in the first period T1. In the first period T1, the optimal corrected read voltage V_{RFC} is generated between the E state and the F state illustrated in FIG. 9.

### Read Operation in First Period T1

At time t0, the sequencer SQC applies the voltage V_{SGD} to the select gate line SGDsel and applies the ground voltage V_{SS} to the unselected gate line SGDusel via the voltage generation circuit VG. The sequencer SQC also applies a first voltage V1 increasing toward the read voltage V_{RF} as the expected voltage value to the selected word line WLsel and applies a second voltage V2 increasing toward the read pass voltage V_{READ} to the unselected word line WLusel via the voltage generation circuit VG. The sequencer SQC also applies a voltage V_{SGS} to the select gate line SGS via the voltage generation circuit VG. The sequencer SQC sets the signal line BLC of the sense amplifier SA to “H” and the signal line CUT to “L” to turn on the clamp transistor 44 and turn off the cutoff transistor 55.

As a result, the sense amplifier SA connected to the selected bit line BLsel charges the selected bit line BLsel, and the voltage of the selected bit line BLsel rises to the voltage VBLsel. On the other hand, the sense amplifier SA connected to the unselected bit line BLusel charges the unselected bit line BLusel, and the voltage of the unselected bit line BLusel rises to the voltage VBLusel. The unselected bit line BLusel is not charged at time t0, and the voltage of the unselected bit line BLusel may be controlled to maintain the ground voltage V_{SS}.

The source line SL is charged by turning on the transistor 63 (FIG. 15) at time t0 to raise the source line SL to the voltage V_{SRC}. The source line SL need not be charged at time t0, and the voltage of the source line SL may be controlled to be maintained at the ground voltage V_{SS}.

The operation of the first period T1 is described in more detail based on FIG. 17. From time t0 to time t01, among the selected memory cells MC connected to the selected word line select line WLsel, the memory cells MC whose threshold voltage Vth is negative voltage and whose state is between the Er state and the C state are turned on, and the memory cells MC whose state is between the D state and the G state are turned off. Assuming that any memory cell MC included in the memory string MS includes the memory cell MC in the G state, the memory cell MC in the G state determines whether or not the cell current Icell flows in each memory string MS. Therefore, as illustrated in FIG. 17, from a time immediately before time t01 at which the second voltage V2 applied to the unselected word line WLusel exceeds the specified read voltage V_{RG} for reading out the memory cell MC in the G state, the cell current Icell begins to flow through the memory string MS including the selected memory cell MC whose state is between the Er state and the C state, and the source current I_{SRC} increases. When the first voltage V1 applied to the selected word line WLsel reaches the specified read voltage V_{RD} for reading out the memory cell MC in the D state at time t01, the selected memory cell MC in the D state also enters the ON state.

When the selected memory cell MC is a memory cell MC with a threshold voltage Vth between the Er state and the D state, a cell current Icell flows through the memory string MS including that memory cell MC. This increases the source current I_{SRC}. Thereafter, the source current I_{SRC} becomes constant. The period during which the source current I_{SRC} becomes constant corresponds to the threshold voltage Vth period between the D state and the E state.

When the first voltage V1 applied to the selected word line WLsel reaches the specified read voltage V_{RE} for reading out the memory cell MC in the E state at time t02, the memory cell MC in the E state is turned on. The second voltage V2 applied to the unselected word line WLusel is larger than the threshold distribution for the G state and smaller than the read pass voltage V_{READ}.

As illustrated in FIG. 17, the source current I_{SRC} increases rapidly after time t02 and then becomes constant. The period during which the source current I_{SRC} becomes constant corresponds to the threshold voltage Vth period between the E state and the F state.

When the first voltage V1 applied to the selected word line WLsel reaches the specified read voltage V_{RF} for reading out the memory cells MC in the F state at time t03, some of the memory cells MC in the F state begin to turn on. Therefore, as illustrated in FIG. 17, the source current I_{SRC} increases slightly after time t03.

As illustrated in FIG. 17, the source current I_{SRC} changes in a staircase pattern, repeating rapid increases and flat sections. This source current I_{SRC} is detected by the source driver circuit SDRV of the source current detection circuit SIDC illustrated in FIG. 15, and the output voltage VI_{SRC} corresponding to the source current I_{SRC} is generated. The output voltage VI_{SRC} is differentiated by the differentiation circuit DIFFa to generate the differential signal dI_{SRC} as illustrated in FIG. 17. The differential signal dI_{SRC} becomes a signal that rises at the part where the source current I_{SRC} changes.

As illustrated in FIG. 17, the source current I_{SRC} and the differential signal dI_{SRC} are the specified values illustrated by the solid line when there is no fluctuation in the threshold voltage Vth. In contrast, when there is a fluctuation in the threshold voltage Vth, the values deviate from the specified values over time, as illustrated by the broken lines. In the example illustrated in the figure, the larger the threshold voltage Vth, the more the threshold voltage Vth is shifted in the direction of becoming smaller than the specified value. Therefore, the search circuit SRCb of the source current detection circuit SIDC (FIG. 15) searches the differential signal dI_{SRC} and searches for a rise timing of the differential signal dI_{SRC} closest to the expected time value T_{RF} or the read voltage V_{RF} as the expected voltage value. Based on the result of this search, information on the corrected read voltage V_{RFC} is output to the sequencer SQC.

### Read Operation in Second Period T2

Next, a data read operation from the selected memory cell MC is executed in the second period T2 using the corrected read voltage V_{RFC} adjusted in the first period T1. Since the specific read operation is the same as in the first embodiment, the detailed description is omitted. In the third embodiment, since the corrected read voltage V_{RFC} is obtained by observing the change in the source current I_{SRC}, the voltage of the bit line BL is not sensed. Therefore, the cutoff transistor 55 of the sense amplifier SA may be omitted.

### Effects of Third Embodiment

According to the third embodiment, the optimal corrected read voltage can be found quickly and accurately by searching the source current I_{SRC}.

### Modification of Third Embodiment

As a modification of the third embodiment, as in the second embodiment, the timing to start applying the first voltage V1 to the selected word line WLsel may be delayed from the timing to start applying the second voltage V2 to the unselected word line WLusel.

### Fourth Embodiment

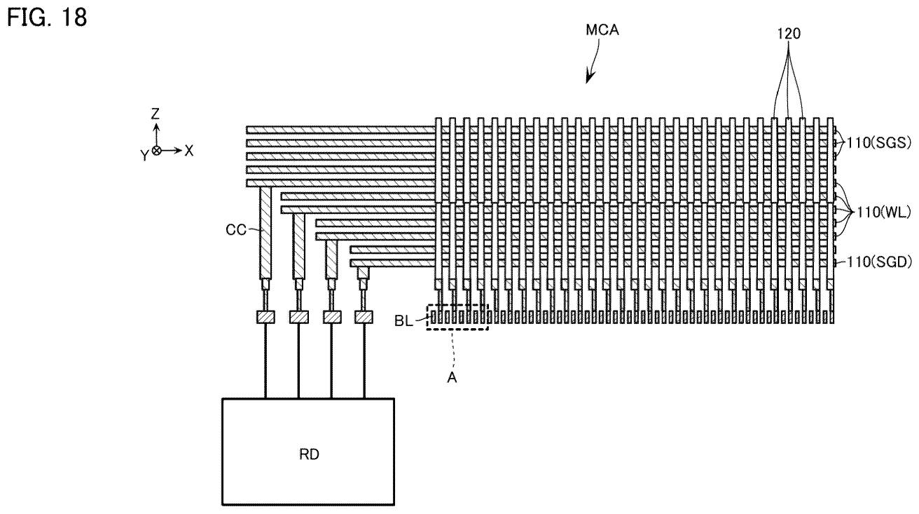

FIG. 18 is a schematic cross-sectional view of the memory die MD according to the fourth embodiment. The memory cell array MCA includes a plurality of conductive layers 110 stacked in the Z-direction and extending in the X-direction, and a plurality of cylindrical semiconductor layers 120 extending in the Z-direction and opposed to the plurality of conductive layers 110 in the XY-direction. The conductive layer 110 arranged at one end in the Z-direction functions as a drain-side select gate line SGD. The conductive layer 110 arranged at the other end in the Z-direction functions as the source-side select gate line SGS. The other conductive layers 110 function as the word lines WL. The semiconductor layer 120, together with the gate insulating layer provided between the conductive layers 110 opposed to one another in the XY-direction, constitutes the memory string MS. A plurality of bit lines BL extending in the Y-direction and arranged in the X-direction are connected to one end of each semiconductor layer 120. One ends in the X-direction of the plurality of conductive layers 110 are connected to a row decoder RD formed on the semiconductor substrate through via-contact electrodes CC.

The plurality of bit lines BL are arranged in the X-direction, and include some bit lines BL (first bit lines) closest to the row decoder RD, that is, the via-contact electrodes CC as illustrated by A in the figure, and other bit lines BL (second bit lines). In the fourth embodiment, during the first period T1 of the read operation, only the cell current Icell flowing in the first bit line BL is detected, and the adjustment process of the corrected read voltage similar to the first to third embodiments is executed.

### Effect of Fourth Embodiment

According to the fourth embodiment, since only the cell current Icell flowing in some bit lines BL closest to the row decoder RD is detected, the delay of the read voltage transmitted to the memory string MS via the word line WL is the smallest. Therefore, the corrected read voltage can be determined at high speed.

### Fifth Embodiment

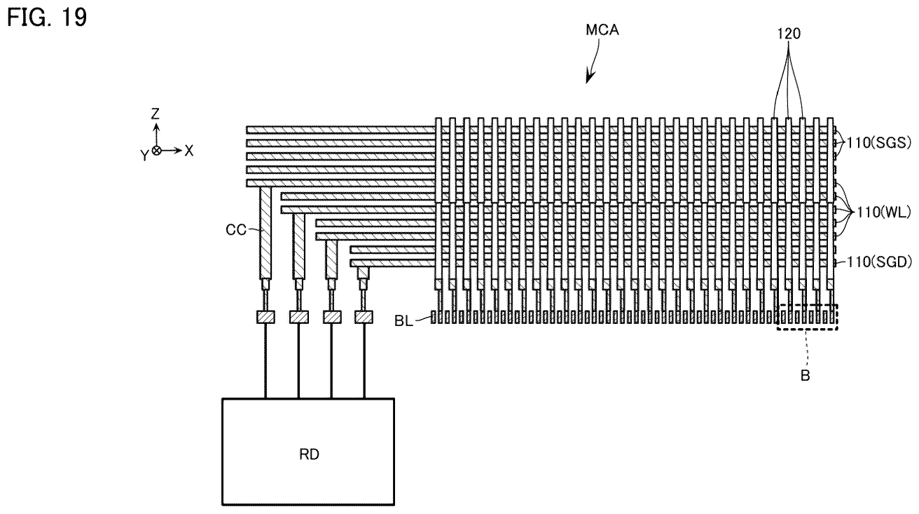

FIG. 19 is a schematic cross-sectional view of the memory die MD according to the fifth embodiment. The memory die MD has the same configuration as the fourth embodiment illustrated in FIG. 18, and thus the detailed description is omitted. The plurality of bit lines BL are arranged in the X-direction, and include some bit lines BL (second bit lines) farthest from the row decoder RD, that is, the via-contact electrode CC as indicated by B in the figure, and other bit lines BL (first bit lines). In the fifth embodiment, during the first period T1 of the read operation, only the cell current Icell flowing in the second bit lines BL is detected, and the same adjustment process of the corrected read voltage as in the first to third embodiments is performed.

### Effect of Fifth Embodiment

According to the fifth embodiment, since only the cell current Icell flowing in some bit lines BL farthest from the row decoder RD is detected, the delay of the read voltage transmitted to the memory string MS via the word line WL is the largest. Therefore, the read voltage applied to the memory string MS can be increased most gradually. This allows the corrected read voltage to be determined more accurately.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of memory strings each including a plurality of memory cells connected in series, the plurality of memory cells being able to store a respective plurality of threshold values;
a plurality of bit lines connected to one end of each of the plurality of memory strings;
a source line connected in common to the other ends of the plurality of memory strings;
a plurality of word lines connected to each of the plurality of memory cells; and
a controller that executes a read operation by applying a first voltage increasing toward a read voltage to a selected word line among the plurality of word lines and applying a second voltage increasing toward a read pass voltage larger than the read voltage to unselected word lines among the plurality of word lines during a first period included in a read operation period, detecting changes in currents flowing through the plurality of bit lines or changes in voltages of the plurality of bit lines and correcting the read voltage based on the changes in the currents or the changes in the voltages during the first period, and reading data from the selected memory cell based on the corrected read voltage during a second period following the first period included in the read operation period.

2. The semiconductor memory device according to claim 1, wherein
the controller includes a sense amplifier module that detects the changes in the voltages of the plurality of bit lines,
the sense amplifier module includes a sense node connected to a bit line, a transistor connected to the sense node, and a capacitor connected to the sense node via the transistor, and
the controller turns off the transistor during the first period to disconnect the sense node from the capacitor, and turns on the transistor during the second period to connect the sense node and the capacitor.

3. The semiconductor memory device according to claim 2, wherein
the sense amplifier module includes a counter that counts a number of the bit lines where the changes in the voltages are detected, and
the controller includes a tracking circuit that determines an amount of correction of the read voltage based on a change in the number of the bit lines counted by the counter.

4. The semiconductor memory device according to claim 1, wherein
the controller includes a source current detection circuit that detects a current flowing through the source line, detects a change in the current flowing through the source line and determines an amount of correction of the read voltage based on the detected change in the current flowing through the source line, during the first period.

5. The semiconductor memory device according to claim 1, wherein
the controller delays a timing at which application of the first voltage to the selected word line starts with respect to a timing at which application of the second voltage to the unselected word lines starts.

6. The semiconductor memory device according to claim 1, wherein
the controller:
during the first period, applies the first voltage increasing toward a first read voltage as the read voltage to the selected word line, and corrects the first read voltage and a second read voltage based on the changes in the currents flowing through the plurality of bit lines or the changes in the voltages of the plurality of bit lines; and
during the second period, sequentially applies the corrected first read voltage and the corrected second read voltage to the selected word line to execute the read operation.

7. The semiconductor memory device according to claim 6, wherein
the first read voltage is larger than the second read voltage.

8. The semiconductor memory device according to claim 1, wherein
the respective plurality of memory strings extend in a first direction, are arranged in a second direction intersecting with the first direction, and are arranged in a third direction intersecting with the first direction and the second direction,
the respective plurality of bit lines extend in the second direction and are arranged in the third direction,
the respective plurality of word lines extend in the third direction and are arranged in the first direction, and
the controller includes a decoder connected to the plurality of word lines via a plurality of via-contact electrodes extending in the first direction.

9. The semiconductor memory device according to claim 8, wherein
the plurality of bit lines include first bit lines and second bit lines arranged in the third direction,
the first bit lines are closer to the via-contact electrode than the second bit lines, and
the controller detects changes in currents flowing through the first bit lines or changes in voltages of the first bit lines and does not detect changes in currents flowing through the second bit lines or changes in voltages of the second bit lines during the first period.

10. The semiconductor memory device according to claim 8, wherein
the plurality of bit lines include first bit lines and second bit lines arranged in the third direction,
the first bit lines are closer to the via-contact electrode than the second bit lines, and
the controller detects changes in currents flowing through the second bit lines or changes in voltages of the second bit lines and does not detect changes in currents flowing through the first bit lines or changes in voltages of the first bit lines during the first period.

11. A semiconductor memory device comprising:
a plurality of memory strings each including a plurality of memory cells connected in series, the plurality of memory cells being able to store a respective plurality of threshold values;
a plurality of bit lines connected to one end of each of the plurality of memory strings;
a source line connected in common to the other ends of the plurality of memory strings;
a plurality of word lines connected to each of the plurality of memory cells; and
a controller that executes a read operation by applying a read voltage to a selected word line among the plurality of word lines, applying a read pass voltage to unselected word lines among the plurality of word lines, and reading data from the selected memory cell connected to the selected word line during a read operation period, wherein
the controller includes a sense amplifier module that detects changes in the voltages of the plurality of bit lines,
the sense amplifier module includes a sense node connected to a bit line, a transistor connected to the sense node, and a capacitor connected to the sense node via the transistor, and
the controller executes a read operation by turning off the transistor during a first period included in the read operation period to disconnect the sense node from the capacitor, turning on the transistor during a second period following the first period included in the read operation period to connect the sense node and the capacitor, detecting changes in currents flowing through the plurality of bit lines or change in voltages of the plurality of bit lines during the first period, correcting the read voltage based on the changes in the currents or the changes in the voltages, and reading data from the selected memory cell based on the corrected read voltage, during the second period.

12. The semiconductor memory device according to claim 11, wherein
the controller applies a first voltage increasing toward the read voltage to the selected word line, and applies a second voltage increasing toward the read pass voltage that is larger than the read voltage to the unselected word lines, during the first period.

13. The semiconductor memory device according to claim 10, wherein
the sense amplifier module includes a counter that counts a number of the bit lines where the changes in the voltages are detected, and
the controller includes a tracking circuit that determines an amount of correction of the read voltage based on the change in the number of bit lines counted by the counter.

14. The semiconductor memory device according to claim 10, wherein
the controller includes a source current detection circuit that detects a current flowing through the source line, detects a change in the current flowing through the source line and determines an amount of correction of the read voltage based on the detected change in the detected current flowing through the source line, during the first period.

15. The semiconductor memory device according to claim 12, wherein
the controller delays a timing at which application of the first voltage to the selected word line starts with respect to a timing of at which application of the second voltage to the unselected word lines starts.

16. The semiconductor memory device according to claim 12, wherein
the controller:
during the first period, applies the first voltage increasing toward a first read voltage as the read voltage to the selected word line, and corrects the first read voltage and a second read voltage based on the changes in the currents flowing through the plurality of bit lines or the changes in the voltages of the plurality of bit lines, and
during the second period, sequentially applies the corrected first read voltage and the corrected second read voltage to the selected word line to execute the read operation.

17. The semiconductor memory device according to claim 16, wherein
the first read voltage is larger than the second read voltage.

18. The semiconductor memory device according to claim 11, wherein
the respective plurality of memory strings extend in a first direction, are arranged in a second direction intersecting with the first direction, and are arranged in a third direction intersecting with the first direction and the second direction,
the respective plurality of bit lines extend in the second direction and are arranged in the third direction,
the respective plurality of word lines extend in the third direction and are arranged in the first direction, and
the controller includes a decoder connected to the plurality of word lines via a plurality of via-contact electrodes extending in the first direction.

19. The semiconductor memory device according to claim 18, wherein
the plurality of bit lines include first bit lines and second bit lines arranged in the third direction,
the first bit lines are closer to the via-contact electrode than the second bit lines, and
the controller detects changes in currents flowing through the first bit lines or changes in voltages of the first bit lines, and does not detect changes in currents flowing through the second bit lines or changes in voltages of the second bit lines during the first period.

20. The semiconductor memory device according to claim 18, wherein
the plurality of bit lines include first bit lines and second bit lines arranged in the third direction,
the first bit lines are closer to the via-contact electrode than the second bit lines, and
the controller detects changes in currents flowing through the second bit lines or changes in voltages of the second bit lines and does not detect changes in currents flowing through the first bit lines or changes in voltages of the first bit lines during the first period.
